(19) United States
(12) Patent Application Publication
(10) Pub. No.: US 2005/0218414 A1
(43) Pub. Date: Oct. 6, 2005

(54) 4H-polytype gallium nitride-based semiconductor device on a 4H-polytype substrate

(76) Inventors: Tetsuzo Ueda, Osaka-fu (JP); Tsunenobu Kimoto, Kyoto-fu (JP); Hiroyuki Matsunami, Kyoto-fu (JP); Jun Suda, Shiga (JP); Norio Onojima, Kyoto city (JP)

Correspondence Address: MCDERMOTT, WILL & EMERY, 600 13th Street, N.W., Washington, DC, 20005-3096, US

(21) Appl. No.: 10/812,416

(22) Filed: Mar. 30, 2004

(51) Int. Cl. H01L 33/00

(52) U.S. Cl. 257/94

(57) ABSTRACT

4H-InGaAlN alloy based optoelectronic and electronic devices on non-polar face are formed on 4H-AlN or 4H-AlGaN on (11-20) a-face 4H-SiC substrates. Typically, non polar 4H-AlN is grown on 4H-SiC (11-20) by molecular beam epitaxy (MBE). Subsequently, III-V nitride device layers are grown by metal organic chemical vapor deposition (MOCVD) with 4H-polytype for all of the layers. The non-polar device does not contain any built-in electric field due to the spontaneous and piezoelectric polarization. The optoelectonic devices on the non-polar face exhibits higher emission efficiency with shorter emission wavelength because the electrons and holes are not spatially separated in the quantum well. Vertical device configuration for lasers and light emitting diodes(LEDs) using conductive 4H-AlGaN interlayer on conductive 4H-SiC substrates makes the chip size and series resistance smaller. The elimination of such electric field also improves the performance of high speed and high power transistors. The details of the epitaxial growth s and the processing procedures for the non-polar III-V nitride devices on the non-polar SiC substrates are also disclosed.

### FIELD OF THE INVENTION

The present invention relates to semiconductor devices using 4H-polytype GaN-based nitride semiconductor epitaxial layers grown on 4H-polytype substrates, and more particularly relates to method for increasing emission efficiency of the GaN-based optoelectronic devices and enabling high speed and high power operations of the GaN-based electronic devices.

### BACKGROUND

III-V nitrides are wide band gap III-V compound semiconductors which contain nitrogen as a group-V element, and generally written as B_{1-x-y-z}InₓAl_{y}Ga_{z}N (0≦x≦1, 0≦y≦1, 0≦z≦1). Such III-V nitrides are widely used for visible light emitting diodes (LEDs) in many applications such as various indicators, traffic signals and so on. In addition, excitation of fluorescent material using the GaN-based blue or ultraviolet LEDs enables emitting white light, which would replace current light bulbs with longer lifetime. A blue-violet GaN-based semiconductor lasers for high-density optical disk systems is also a promising application of III-V nitrides. At present, III-V nitride lasers are commercially available for proto-type high density optical disk systems. High speed and high power GaN-based transistors are potential applications as well.

Due to the difficulties to obtain lattice-matched III-V nitride substrates, conventional III-V nitride devices are grown on foreign substrates such as sapphire or SiC. Among such foreign substrates, SiC is very promising since it has closer lattice constant from that of III-V nitrides as well as better thermal conductivity. SiC is also well-known material which has polytypism such as 3C-, 4H-, 6H-, 15R-type. So far, epitaxial growth of III-V nitrides on the various SiC polytypes are disclosed.

Karino et al. (Japanese Patent Published H8-125275) disclosed hexagonal III-V nitride-based laser devices on 2H-, 4H- and 6H-polytypes of (11-20) a-face or (10-10) m-face SiC substrates.

Hatano et al. (U.S. Pat. No. 5,432,808) disclosed formation of InGaAlN-based device on 3C (cubic) SiC (111) substrate.

Stummer et al. (Physical Review Letters Vol. 77, No. 9, (1996) p. 1797-1799) explained the epitaxial growth of 2H-AlN on 6H-SiC substrate.

However, how the combination of the polytype of SiC substrate and that of the overgrown III-V nitrides affect the crystal quality is not still clear. This invention is disclosed based on experimental results by inventors of this disclosure to find the best combination of the polytypes in view of crystal quality.

### SUMMARY OF THE INVENTION

Accordingly, it is an object of present invention to provide the best combination of the polytypes for both SiC substrate and the overgrown III-V nitrides. The present invention provides a structure and method for overcoming many of the aforesaid limitations of the prior art by choosing the best combination of the polytypes, as summarized below and described in greater detail hereinafter.

The present invention provides a semiconductor device comprising a 4H-type epitaxial III-V nitride film grown on a 4H-type substrate. The substrate material is preferably SiC, and/or preferably (11-20) a-face. The III-V nitride epitaxial film preferably comprises AlN. The number of the group III atoms on the surface of the III-V nitride film is preferably equal to the number of nitrogen atoms on the surface.

In a somewhat different application, the present invention also provides a semiconductor laser comprising a 4H-type epitaxial III-V nitride film grown on a 4H-type substrate. The substrate material is preferably SiC, and/or preferably (11-20) a-face. The III-V nitride epitaxial film preferably comprises AlN. The number of the group III atoms on the surface of the III-V nitride film is preferably equal to the number of nitrogen atoms on the surface. It is also preferred that the waveguide is formed as a straight line perpendicular to either (0001) face or (1-100) face. The III-V nitride preferably contains either 4H-AlN or conductive 4H-AlGaN as a initial layer of the epitaxial growth. Highly conductive p-type 4H-SiC is preferably used with p-type 4H-AlGaN initial layer. The semiconductor laser may contain laterally epitaxial grown layers with reduced dislocation density on which the waveguide is formed. The seed layer of the lateral epitaxial growth is preferably 4H-GaN on 4H-AlN. It is also preferred that the lateral growth starts from the 4H-GaN and preferably air gaps are formed between the SiC substrate and the laterally grown layer. The semiconductor laser is preferably cleaved along to either <0001> or <1-100> direction.

In a somewhat different application, the present invention also provides a light emitting diode(LED) comprising a 4H-type epitaxial III-V nitride film grown on a 4H-type substrate. The substrate material is preferably SiC, and/or preferably (11-20) a-face. The III-V nitride epitaxial film preferably comprises AlN. The number of the group III atoms on the surface of the III-V nitride film is preferably equal to the number of nitrogen atoms on the surface. It is also preferred that the SiC substrate is p-type and the top layer of the III-V nitride layer is n-type on which ohmic contact is formed without any transparent electrode.

In a somewhat different application, the present invention also provides a transistor comprising a 4H-type epitaxial III-V nitride film grown on a 4H-type substrate. The substrate material is preferably SiC, and/or preferably (11-20) a-face. The III-V nitride epitaxial film preferably comprises AlN. The number of the group III atoms on the surface of the III-V nitride film is preferably equal to the number of nitrogen atoms on the surface. It is also preferred that the III-V nitride film comprises AlGaN on GaN or AlGaN on InGaN on GaN heterostructure. The III-V nitride film preferably comprises modulation-doped layers.

In a somewhat different application, the present invention also provides fabrication methods of semiconductor laser, light emitting diode, and transistor comprising a 4H-type epitaxial III-V nitride film grown on a 4H-type substrate. The substrate material is preferably SiC, and/or preferably (11-20) a-face. The III-V nitride epitaxial film preferably comprises AlN. The number of the group III atoms on the surface of the III-V nitride film is preferably equal to the number of nitrogen atoms on the surface. The fabrication method of a semiconductor laser may contain lateral epitaxial growth and preferably the seed layer of the lateral growth may be selectively etched 4H-GaN on 4H-AlN. It is also preferred that the lateral growth starts from the 4H-GaN so that air gaps are formed between the SiC substrate and the laterally grown layer.

These and other objects, advantages and features of the invention will be set forth in part in the description which follows and in part will become apparent to those having ordinary skill in the art upon examination of the following, or may be learned from the practice of the invention. The advantages of the invention may be realized and attained as particularly pointed out in the attained claims.

### BRIEF DESCRIPTION OF THE DRAWINGS

FIG. 1 is a cross sectional view of a III-V nitride-based blue-violet seemiconductor laser with 4H-polytype on 4H-AlN/4H-SiC as one embodiment of the present invention.

FIG. 2 is an illustration of atomic configuration on 4H-SiC (11-20) a-face.

FIG. 3 is an illustration of atomic configuration on 6H-SiC (11-20) a-face.

FIG. 4 is an illustration of atomic configuration on 2H-AlN (11-20) a-face as is also seen in all of the III-V nitride with 2H-polytype.

FIG. 5 is an illustration of band diagram of InGaN/GaN quantum well with 2H-polytype on a polar c-face substrate.

FIG. 6 is an illustration of band diagram of InGaN/GaN quantum well with 4H-polytype on a non-polar a-face substrate.

FIG. 7 is an illustration of atomic arrangement of AlN on SiC substrate both on polar and non-polar faces.

FIG. 8 is processing flow of epitaxial growth of III-V nitride layers with initial AlN buffer layer on a 4H-SiC(11-20) substrate.

FIG. 9 is reflection high-energy electron diffraction (RHEED) patterns of AlN layer on a 4H-SiC(11-20) substrate and on a 6H-SiC(11-20) substrate.

FIG. 10 is lattice images of AlN on 4H-SiC(11-20) and AlN on 6H-SiC(11-20) measured by high resolution transmission electron microscope (HRTEM).

FIG. 11 is x-ray rocking curve profiles on (11-20) diffraction for AlN on 4H-SiC(11-20) and on 6H-SiC(11-20).

FIG. 12 is a cross sectional illustration of a III-V nitride-based blue-violet seemiconductor laser with 4H-polytype on 4H-AlN/4H-SiC in which the laser structure is formed epitaxial regrowth from narrow striped GaN/AlN seed layer as one embodiment of the present invention.

FIG. 13 is a cross sectional illustration of a III-V nitride-based blue-violet seemiconductor laser with 4H-polytype on conductive 4H-AlN/4H-SiC in which the electrodes are formed on the both sides as one embodiment of the present invention.

FIG. 14 is a cross sectional illustration of a III-V nitride-based ultravioler LED with 4H-polytype on conductive 4H-AlN/4H—SiC in which the electrodes are formed on the both sides as one embodiment of the present invention.

FIG. 15 is a cross sectional illustration of a III-V nitride-based heterostructure transistor with 4H-polytype on 4H-AlN/4H—SiC as one embodiment of the present invention.

### DETAILED DESCRIPTION OF THE PREFERRED EMBODIMENTS

### First Embodiment

(Device Structure)

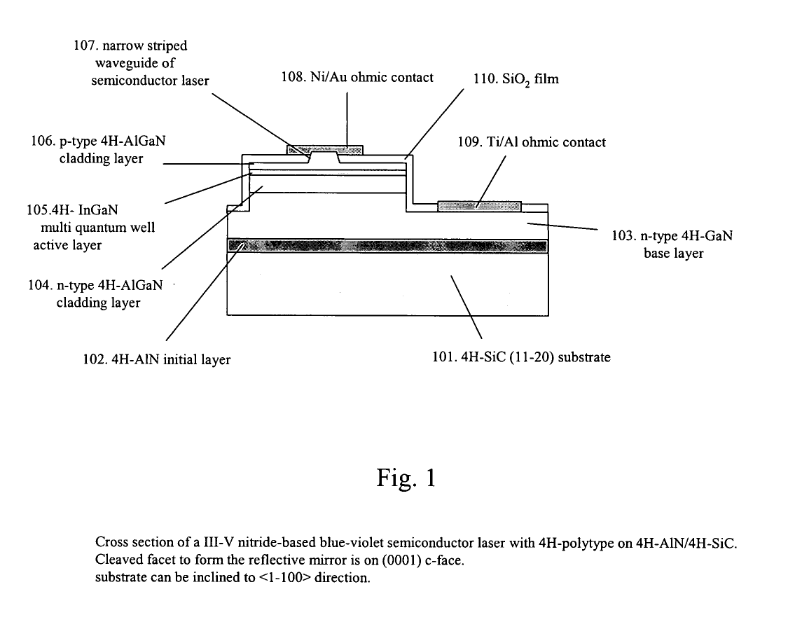

Referring first to FIG. 1, one embodiment of the semiconductor laser of the present invention may be understood in greater detail. In particular, FIG. 1 schematically illustrates a cross sectional view of a blue-violet semiconductor laser in which GaN-based epitaxial structure with 4H polytype is grown on (11-20) a-face of 4H-SiC substrate. The GaN-based epitaxial structure typically consists of p-type Al_{0.07}Ga_{0.93}N cladding layer 106, undoped InGaN multi quantum well active layer 105, n-type Al_{0.07}Ga_{0.93}N cladding layer 104 and n-type GaN base layer 103 And the undoped InGaN multi quantum well active layer 105 is disposed between the p-type AlGaN cladding layer 106 and n-type AlGaN cladding layer 104, and these three layers are formed on the n-type GaN base layer 103 as shown in FIG. 1. Moreover, n-type GaN base layer 103 is formed on the undoped AlN initial layer 102. All of the epitaxial layers have 4H poly type and the layers are grown replicating the poly type of the 4H-SiC substrate 101. In this embodiment, the word, GaN-based epitaxial structure has the structure including an epitaxial layer of which composition includes Ga and N. In this structure, cladding layer 104, active layer 105, and cladding layer 106 has the composition of Ga and N.

Detailed structural parameters of the semiconductor laser are summarized in Table 1. Table 1 shows the example for the thickness of each layer and the carrier concentrations of some layers including Ga and N. In Table 1, the carrier concentrations of p-AlGaN cladding layer and n-AlGaN cladding layer are substantially same, and the carrier concentration of the cladding layer is higher than the base layer. The active layer 105 has the quantum well and barrier layer. As shown in table 1, the composition of the well layer is undoped In0.1Ga0.9N, and the composition of the barrier layer is undoped In0.02Ga0.98N. The thickness of the well layer and the barrier layer is 4 nm. And the number of the well layer in the active layer 105 is three.

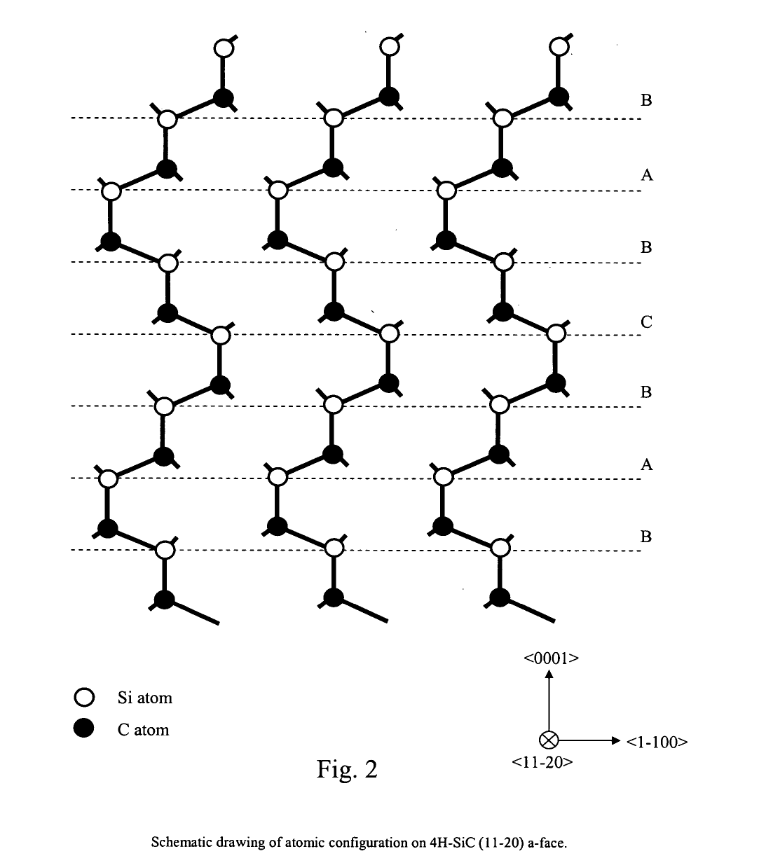

The (11-20) face represents the stacking sequence of the consisting atomic pair as shown in FIG. 2. The atomic configuration on (11-20) shows the ABCB ABCB . . . sequence and the GaN-based epitaxial layer inherits the sequence without forming any dislocations by choosing appropriate growth conditions. Replacing the Si and C atoms to Al and N atoms respectively in FIG. 2 represents the atomic configuration of the overgrown 4H-AlN layer.

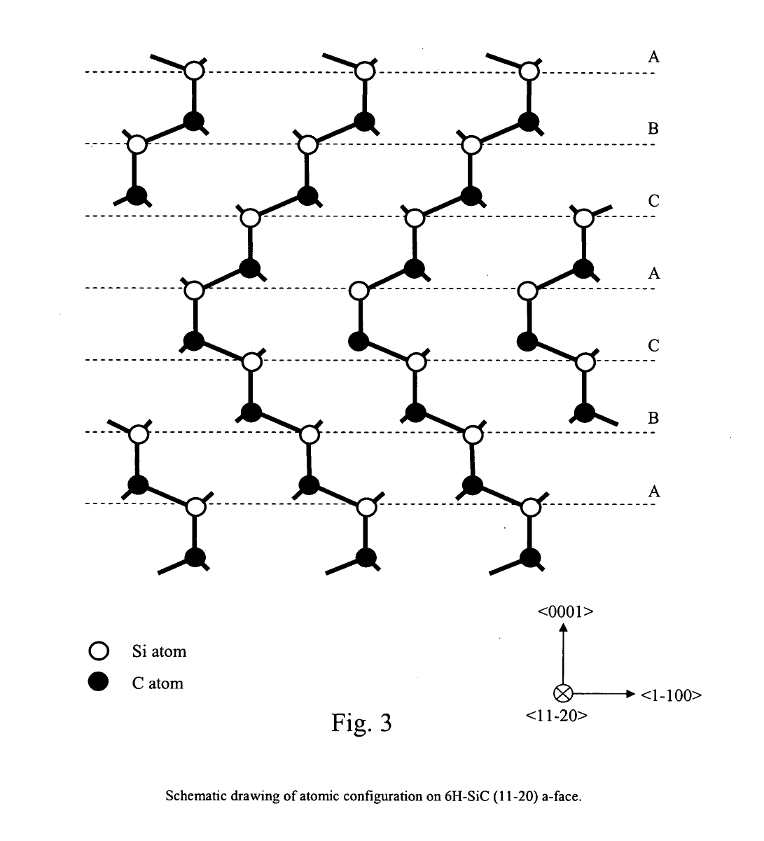

On the other hand, in case the used substrate is 6H-SiC (11-20) face, of which the atomic configuration is shown in FIG. 3. The atomic configuration on (11-20) shows the ABCACB ABCACB . . . sequence and the grown III-V nitride on the 6H face exhibits thermally stable 2H-polytype.

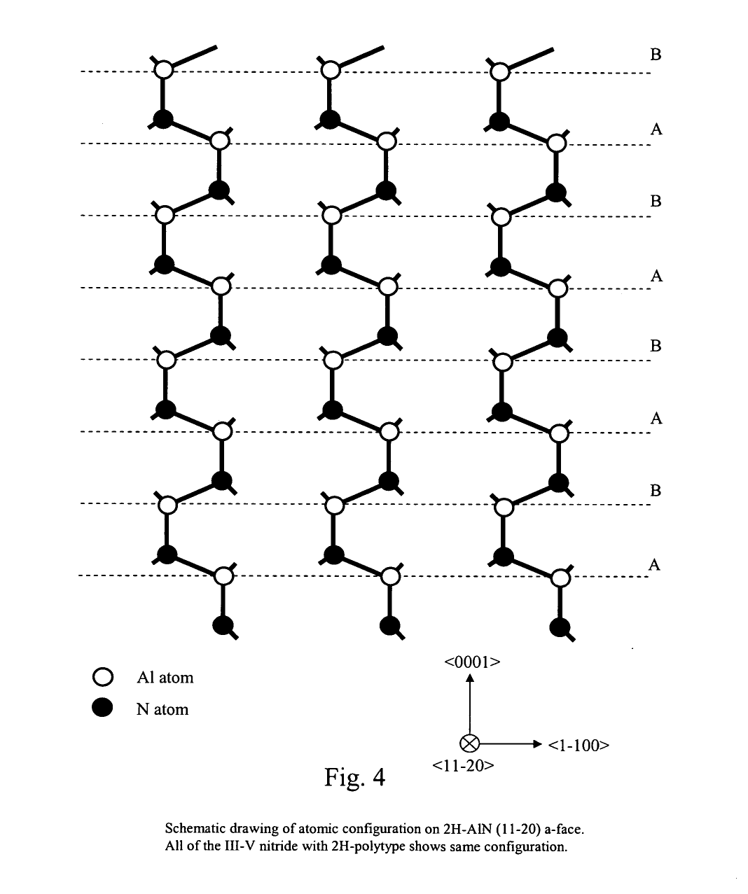

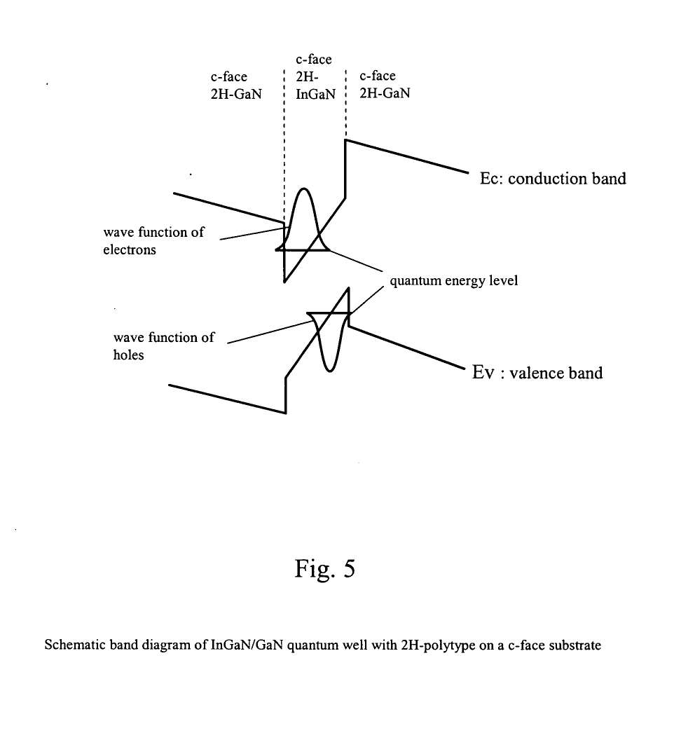

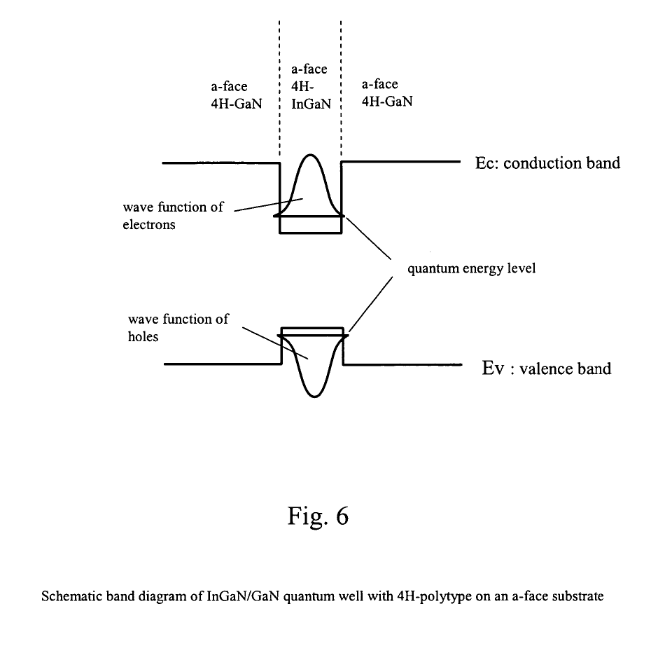

FIG. 4 shows the atomic configuration of the overgrown 2H-AlN on (11-20) a-face and the atomic configuration on (11-20) shows the AB AB AB . . . sequence. As is easily expected from FIG. 5 and FIG. 6, the overgrown 2H-configuration contains a lot of faulted region due to the disarrangement of the atoms at the interface.

In contrast the 4H-AlN on 4H-SiC (11-20) heterostructure does not contain such disarrangement as is described below in detail. The (11-20) is so-called non polar face on which both group III and nitrogen atoms are located. On the other hand, commonly used (0001) c-face of the III-V nitride device layer is polar face on which either group III or nitrogen atoms are located. Since polarization is aligned along (0001) direction of III-V nitride epitaxial films, the build in electric fields are produced by the spontaneous and piezoelectric polarization on such polar face. The electric field in the quantum well structure results in lower light emission efficiency with the longer wavelength, which is so-called quantum confined Stark effect. Even undoped AlGaN/GaN hetero structure exhibits sheet carrier concentration in the order of 10¹³ cm⁻² as well. FIG. 5 shows the band diagram of the quantum wells on the polar face. This quantum well structure is composed of the 2H-InGaN well layer and 2H-GaN barrier layer. This figure shows the wave functions both of electrons and holes in the quantum well. The band is distorted due to the electric field mainly by the piezoelectric polarization. The electrons and holes are spatially separated in the well so that the emission efficiency is reduced. That is, it needs much larger electron energy to maintain high emission efficiency because of the separation of the electrons and holes shown in FIG. 5. In addition, the emission wavelength is longer than that without any electric field.

On the contrary, the double hetero epi-structure with 4H-polytypes with non polar a-face described in the first embodiment exhibits a band structure as shown in FIG. 6. In this FIG. 6, this quantum well structure is composed of the 2H-InGaN well layer and 2H-GaN barrier layer. Since the a-face is a non-polar face, any polarization-induced electric field is not seen perpendicular to the quantum well in the band diagram. Thus, emission efficiency from the quantum well is increased from that on the polar c-face with such electric field due to the polarization. Note that the wavelength of the emitted light is shorter than that on the polar face.

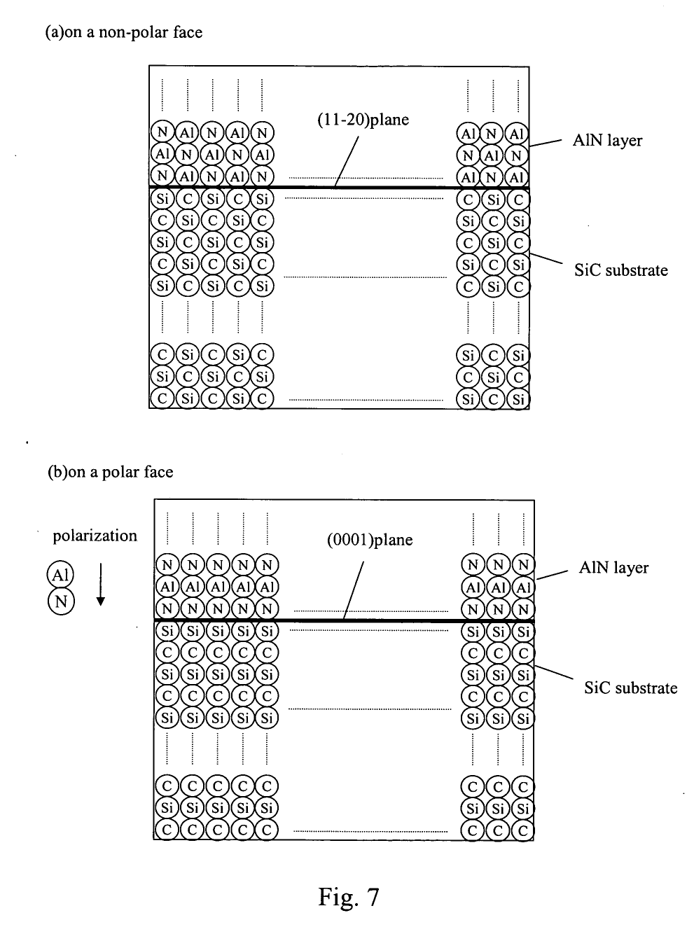

FIG. 7 schematically summarizes the atomic arrangement both on the non-polar and polar faces with the direction of the produced polarization. In FIG. 7(a) the boundary surface between AlN layer and SiC substrate has a mixed crystal structure comprising Al, N, Si, C so that these atomic polarizations are neglected each other. However, in FIG. 7 (b) the boundary surface between AlN layer and SiC substrate comprises single crystal multi layers deposited each other so that atomic polarization is generated especially on the boundary surface as indication by an arrow.

(Fabrication Process)

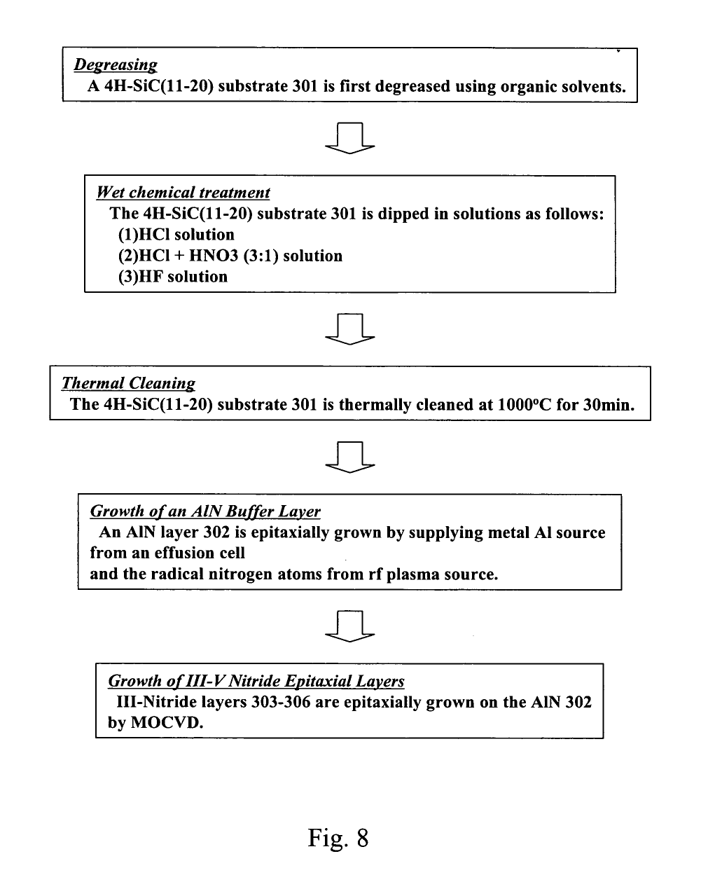

Referring next to FIG. 8, the detailed structure and the process sequences of the semiconductor laser as the first embodiment are described as follows.

First, 380 nm-thick 4H-AlN is grown on a surface of a 4H-SiC (11-20) substrate 301 by molecular beam epitaxy (MBE).

In a degreasing step the 4H-SiC (11-20) substrate 301 is first degreased using organic solvents.

In a wet chemical treatment step the 4H-SiC (11-20) substrate 301 is dipped in solutions in turn. First solution is HCl, second solution is HCl+HNO3 (3:1) and third solution HF.

In a thermal cleaning step the 4H-SiC (11-20) substrate 301 is thermally cleaned at 1000° C. for 30 minutes to make a flat and/or a clean surface of the substrate 301, and then loaded into the MBE chamber.

Then, in a growth of an AlN buffer layer step the AlN layer 302 is epitaxially grown by supplying metal Al source from an effusion cell and the radical nitrogen atoms from RF plasma source. Typical growth temperature for the AlN layer is 1000° C. with an Al beam equivalent pressure of 4.7×10⁻⁷ Torr and RF power of 400 W with a nitrogen flow rate of 0.5 sccm. The growth rate under the condition is 380nm/hr.

After the MBE growth, in a growth of III-V nitride epitaxially layers step the wafer is reloaded to a metal organic chemical vapor deposition (MOCVD) reactor to grow GaN-based double hetero structure for the blue-violet laser. Trimethyl gallium (TMGa) and ammonia are supplied for the GaN growth.

Trimethyl aluminum (TMAl) and/or trimethyl indium (TMIn) are added for the ternary or quaternary alloy growth. Cp₂Mg and SiH₄ are used for the p-type and n-type doping, respectively. As shown in FIG. 1, 4 μm-thick n-GaN is grown on the MBE-grown 4H-AlN layer 102. The GaN layer exhibits 4H-polytype on (11-20) face. Subsequently, 1 μm-thick n-Al_{0.07}Ga_{0.93}N cladding layer 104, undoped InGaN multi-quantum well active layers 105, 0.5 μm-thick p-Al_{0.07}Ga_{0.93}N cladding layer 106 is grown on the n-GaN layer 103. Both n-GaN layer and p-GaN layer guiding layer typically with the thickness of 100 nm may be attached on and underneath the active layers 105. P-AlGaN with higher Al content may be placed between the p-type cladding layer 106 and the active layer 105 to suppress the overflow of the electrons. P-GaN with high Mg concentration may be grown on the top of the p-Al_{0.07}Ga_{0.93}N cladding layer 106. All of the regrowth layer by MOCVD exhibit 4H-polytype inheriting the atomic sequence of 4H-AlN layer. Thus obtained non-polar active layer does not affected by the built-in electric field due to the piezoelectric polarization so that higher emission efficiency with shorter wavelength is possible.

Dry etching process such as inductive coupled plasma (ICP) etching using Cl₂ selectively etches the p-type AlGaN cladding layer 106 to form the straight ridge-shaped waveguide using a patterned photo resist as a mask. Then, the same etching technique etches the active layer 105 and cladding layer 104 to expose the n-GaN layer 103 prior to the ohmic contact 109 formations on it.

After the two processing steps of the dry etching, a 300 nm-thick SiO₂ film 110 is deposited, typically by using plasma assisted chemical vapor deposition. The SiO₂ film 110 on the side wall of the ridge-shaped waveguide confines the emitted light inside the ridge structure due to the difference of the effective refractive index between the SiO₂ 110 and the cladding layer 106. Ni/Au layer(electrode) 108 as a ohmic contact on p-AlGaN cladding layer 106 and Ti/Al layer(electrode) 109 as a ohmic contact on n-GaN 103 are formed after the selective wet chemical etching of SiO₂ film 110 where the ohmic contacts are to be formed. The processed substrate is thinned from the back side typically down to 150 μm. The cleaved facets are formed along to <0001> axis to form mirrors of the laser. Typical cavity length is 600 μm. The fabricated laser exhibits lower threshold current density because of high emission efficiency on the non-polar face.

(Characterization of Initial AlN Epitaxial Layer)

The AlN initial epitaxial layer is characterized in detail as is described below.

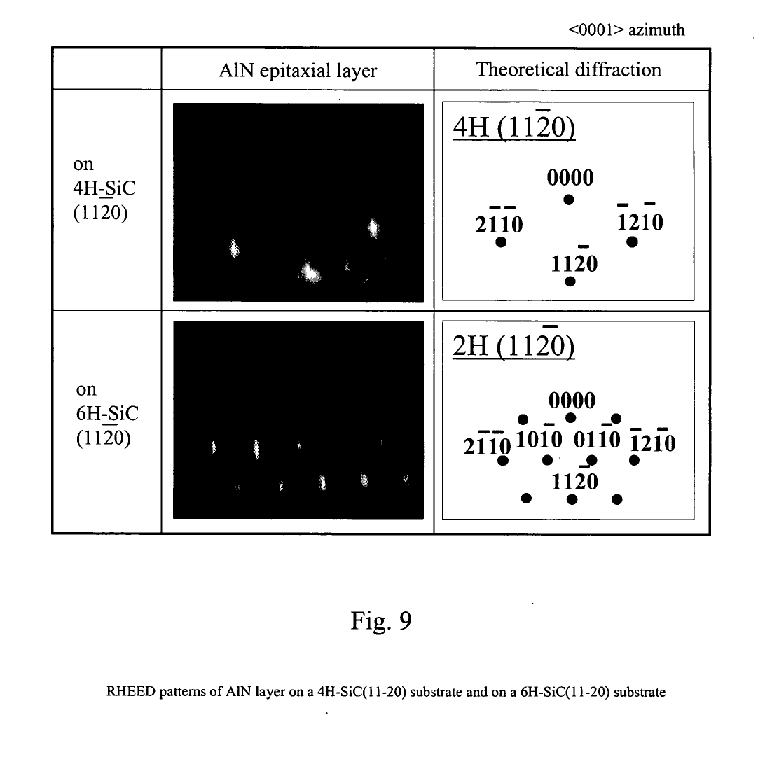

FIG. 9 shows the reflection high energy electron diffraction (RHEED) pattern of the AlN layer on 4H-SiC and 6H-SiC. The pattern of AlN on 4H-SiC well corresponds with that of 4H-polytype, whereas the pattern of AlN on 6H-SiC indicates 2H-polytype. The polytype is replicated in AlN epitaxial layer from 4H-SiC substrate.

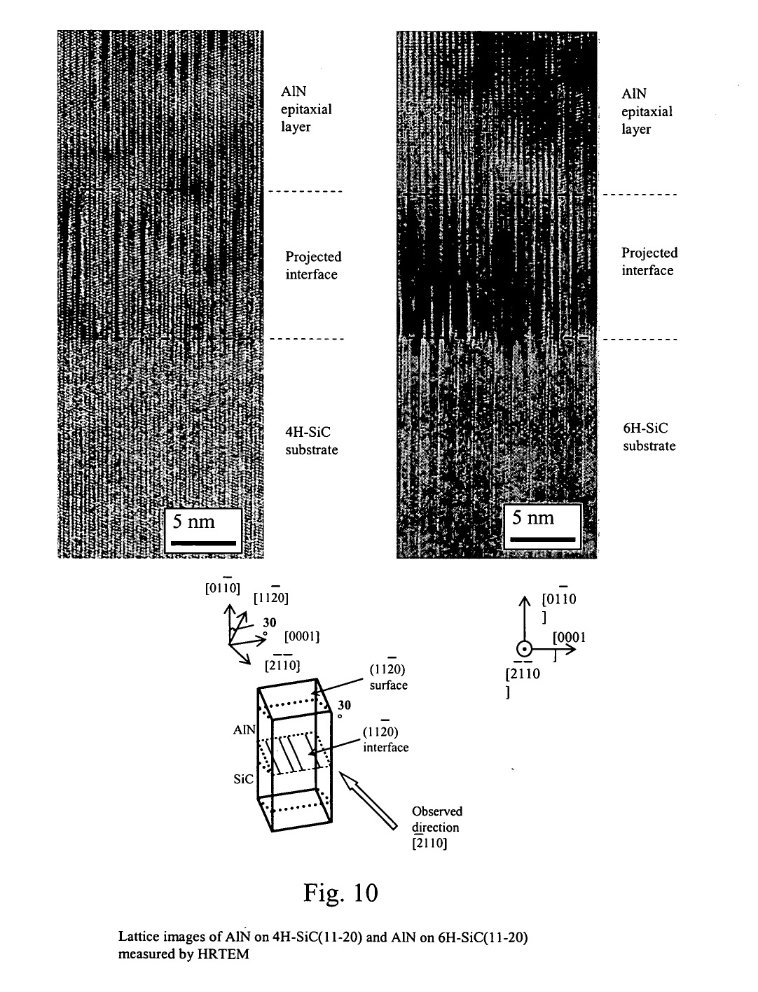

FIG. 10 shows the microscopic structure of the AlN/4H-SiC (11-20) substrate and AlN/6H-SiC (11-20) substrate investigated by high-resolution transmission electron microscope (HRTEM). In order to clarify the stacking sequence in the AlN layer, a TEM sample is cut from the wafer with a 30° inclination as shown in FIG. 10. As is seen in the 4H-SiC substrate region, one set of dark and bright bands corresponds to one unit cell of the 4H structure. The AlN epitaxial layer has just the same dark bright bands, indicating successful polytypic replication from the 4H-SiC substrate. The AlN epitaxial layer is the 4H polytype structure. On the contrary, as shown in FIG. 9, AlN epitaxial layer on 6H-SiC (11-20) exhibits 2H-polytype.

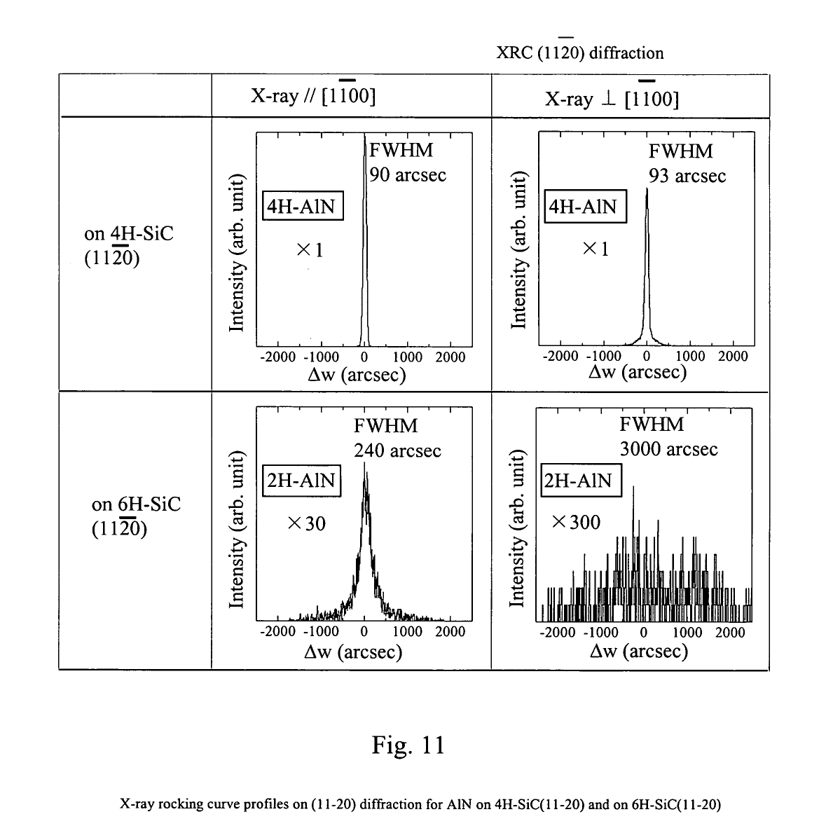

FIG. 11 shows the x-ray rocking curves (XRC) of (11-20) diffraction for 380 nm-thick AlN epitaxial layers on 4H-SiC (11-20) substrate and 6H-SiC (11-20) substrate. Two different x-ray incident geometries parallel and perpendicular to the <1-100> direction are examined. The full width at half maximum (FWHM) exhibited a very small value of 90 arcsec, suggesting noticeably small tilting around the <11-20> direction. On the contrary, AlN layer on 6H-SiC substrate exhibited a large FWHM of 240 arcsec with the x-ray incident parallel to <1-100> as well as the peak is very weak. Thus, the crystal quality of the AlN epitaxial layer on 4H-SiC(11-20) substrate is much superior to that grown on the 6H-SiC(11-20) substrate. The poor crystal quality of the AlN on 6H-SiC substrate is probably attributed to many stacking faults or line defects, which is originated from polytype mismatch of 2H-AlN on 6H-SiC.substrate. The poor crystal quality would lead to higher operating current of the laser with shorter life time due to the non irradiative recombination centers caused by the crystal defects. The defect degrades the performances of the other kinds of devices as well.

The above-mentioned results shown in FIG. 9-11 are summarized in Table 2.Table 2 describe the difference between the present invention and the compared example. The present invention has a 4H-a-face of AlN layer formed on a 4H-SiC substrate and the compared example has a 2H-a-face AlN layer formed on a 6H-SiC substrate. As shown in this table 2, The combination of the overgrown layer with the 4H face and the substrate with 4H face is better than the combination of the overgrown layer with 2H face and the substrate with 6H face on these points such as “poly-type matching, crystal quality, and device performance”. In this table, poly-type matching means the same indication of the poly-type between substrate and overgrown layer.

### Second Embodiment

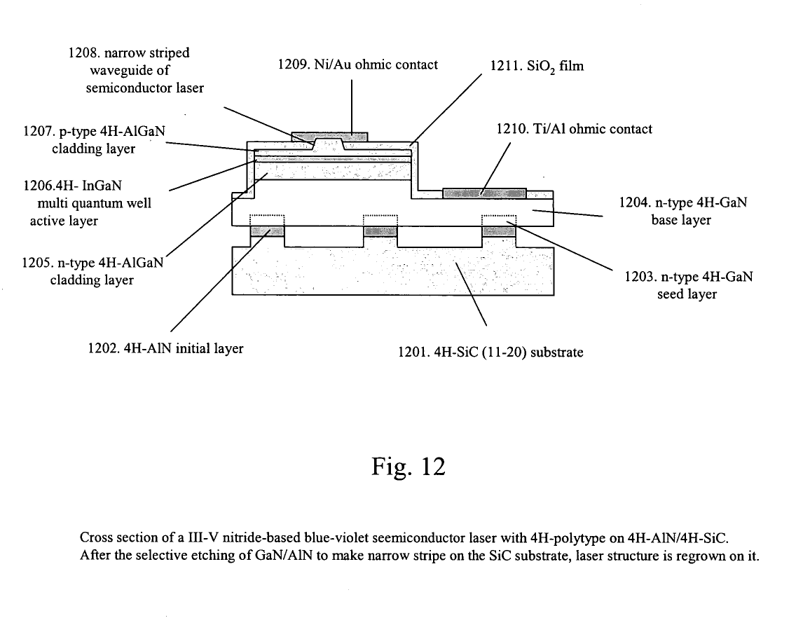

Referring next to FIG. 12, there is schematic illustration of a non-polar GaN based blue-violet semiconductor laser on a 4H-SiC (11-20) a-face substrate 1201. Basic epitaxial structures on 4H-SiC (11-20) a-face is identical with the structure as shown in FIG. 1. However, dislocation density in the active layer underneath the waveguide 1208 is further reduced by employing the epitaxial lateral over growth technique. The resultant laser exhibits longer lifetime than that without any lateral growth region owing to the reduction of the dislocations. The emission efficiency from the quantum well in the laser is increased from that on the polar c-face with built-in electric field due to the polarization, which leads to lower threshold current density.

As shown in FIG. 12, the epitaxial structure of the laser typically consists of an undoped InGaN multi quantum well active layer 1206 formed between a p-type Al_{0.07}Ga_{0.93}N cladding layer 1207 and an n-type Al_{0.07}Ga_{0.93}N cladding layer 1205 and n-type GaN base layer 1204 formed under the n-type Al_{0.07}Ga_{0.93}N cladding layer 1205. Under the n-GaN base layer 1204, 380 nm-thick AlN initial layer 1202 is formed selectively in the shape of narrow stripe. The stripe is formed in the surface of the 4H-SiC substrate 1201. The stripe width is typically 5 μm and the distance of each stripe is 15 μm. Dislocation density at the active layer 1206 underneath the waveguide 1208 is at around 1×10⁶ cm² or less, because the lateral growth reduces the dislocation density. The direction of the stripe is preferably <1-100> direction, which is perpendicular to the stacking direction. Resultant lateral growth to <1-100> keeps the poly type in the wing region 1212 from that in the seed region 1203.

On the contrary, if the direction of the stripe is <0001> direction, the stacking order of the atoms in the wing region 1212 is determined by the growth condition rather than the stacking order in the wing region 1212. The detailed structural parameters of the semiconductor laser are summarized in Table 3. Table 3 discloses the thickness and carrier concentration each layers in one example. In Table.3 a p-type AlGaN cladding layer has substantially same carrier concentration “5×10¹⁷ cm³” as an n-type AlGaN cladding layer, and an n-type GaN base layer has substantially same carrier concentration “1×10¹⁸ cm³” as an n-type GaN seed layer. And an undoped AlN layer 1202 and an undoped quantum wells 1206 is not doped. The active layer 1206 has the quantum well and barrier layer. As shown in table 2, the composition of the well layer is undoped In0.1Ga0.9N, and the composition of the barrier layer is undoped In0.02Ga0.98N. The thickness of the well layer and the barrier layer is 4 nm. And the number of the well layer in the active layer 105 is three.

The detailed processing procedures are as follows. First, 380 nm-thick 4H-AlN is grown on 4H-SiC(l 1-20) face by molecular beam epitaxy (MBE) Details is described same as in the first embodiment as following.

In a degreasing step the 4H-SiC (11-20) substrate 1201 is first degreased using organic solvents.

In a wet chemical treatment step the 4H-SiC (11-20) substrate 1201 is dipped in solutions in turn. First solution is HCl, second solution is HCl+HNO3 (3:1) and third solution HF.

In a thermal cleaning step the 4H-SiC (11-20) substrate 1201 is thermally cleaned at 1000° C. for 30 min to make a flat and/or a clean surface of the substrate, and then loaded into the MBE chamber.

Then, in a growth of an AlN buffer layer step the AlN layer 1202 is epitaxially grown by supplying metal Al source from an effusion cell and the radical nitrogen atoms from RF plasma source. Typical growth temperature for the AlN layer is 1000° C. with an Al beam equivalent pressure of 4.7×10⁻⁷ torr and RF power of 400 W with a nitrogen flow rate of 0.5 sccm. The growth rate under the condition is 380 nm/hr.

After the MBE growth, n-type 4H-GaN seed layer 1203 having 2 μm-thickness is grown on the 4H-AlN initial layer 1202 by MOCVD.

Then, the n-type 4H-GaN seed layer 1203 and the 4H-AlN initial layer 1202 are selectively etched by dry etching such as ICP etching. Stripe pattern along to <0001> direction with the width of typically 5 μm is formed. Preferably, as shown in FIG. 12, grooves in SiC between wing regions 1212 such as GaN/AlN stripes are formed subsequently by the same etching procedure.

After the stripe patterning, n-type 4H-GaN base layer having 4 μm thicknesses is grown on the stripes by lateral epitaxial growth. The laterally growth reduced dislocation density from that at the stripe region of the n-type 4H-GaN seed layer 1203. Note that the lateral growth takes place from the n-type 4H-GaN seed layer 1203 on the stripe of the 4H-AlN initial layer 1202, so that the no epitaxial film is grown on the sidewall of the 4H-AlN initial layer 1202. Subsequently, n-type 4H-Al_{0.07}Ga_{0.93}N cladding layer 1205 having 1 μm-thickness, an undoped InGaN multi-quantum well active layers 1206, p-type 4H-Al_{0.07}Ga_{0.93}N cladding layer 1207 having 0.5 μm-thickness are grown on the n-type 4H-GaN base layer 1204. All of the epitaxial growth layers exhibit 4H-polytype inheriting the atomic sequence of 4H-AlN initial layer 1202.

Following dry etching processes selectively etches the p-type 4H AlGaN cladding layer 1207 to form the straight ridge-shaped waveguide 1208 as well as the 4H-InGaN multi quantum well active layer 1206 and n-type 4H AlGaN cladding layer 1205 to expose the n-type 4H-GaN base layer 1204.

After the etching steps, a 300 nm-thick SiO₂ film 1211 is deposited to confine the emitted light in the waveguide 1208. Ni/Au layer(electrode) 1209 as a p-ohmic contact and Ti/Al layer(electrode) 1210 as an n-ohmic contact are formed in contact with the SiO2 film 1209. The substrate thinning process followed by the cleaving process is conducted to fabricate a blue-violet laser diodes on the non-polar face with lower threshold current density.

### Third Embodiment

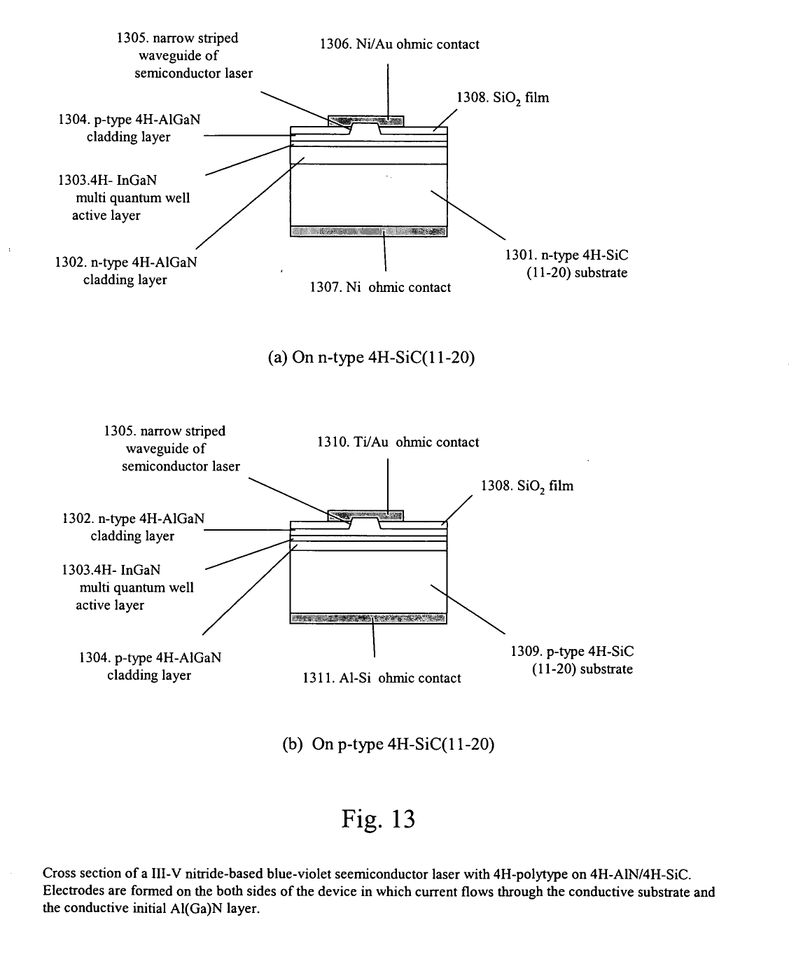

Referring next to FIG. 13(a) and (b), non-polar GaN-based blue-violet laser diodes on 4H-SiC (11-20) a-face substrates with two electrodes on the both sides of the laser chip are shown. Epitaxial structure on 4H-SiC (11-20) a-face is basically identical with the structure shown as the first embodiment except for the initial layer. In the first embodiment, the initial layer is AlN, however in this embodiment, the initial layer which is formed on the substrate 1301 is conductive AlGaN layer. And also in this embodiment, the 4H-SiC substrate 1301 is conductive to enable the vertical device configuration. The emission efficiency from the quantum well in the laser on the non polar face is increased from that on the polar c-face with built-in electric field due to the polarization, which leads to lower threshold current density together with low series resistance and operating voltage owing to its vertical device configuration.

As shown in FIG. 13(a) and (b), the epitaxial structure of the laser typically consists of p-type Al_{0.07}Ga_{0.93}N cladding layer 1304, undoped InGaN multi quantum well active layer 1303, n-type Al_{0.07}Ga_{0.93}N cladding layer 1302.

The laser structure on n-type 4H-SiC 1301 as shown in FIG. 13(a) has an n-type 4H-AlGaN initial layer as a part of the n-type 4H-cladding AlGaN layer 1302. In this device 4H-InGaN multi quantum well active layer 1303 is formed between n-type 4H-cladding AlGaN layer 1302 and p-type 4H-cladding AlGaN layer 1304, and a waveguide of a semiconductor laser 1305 is formed on the p-type 4H-cladding AlGaN layer 1304. Additionally these GaN based epitaxial structure are formed between ohmic contacts. That is Ni/Au ohmic contact(electrode) 1306 is contacted with the waveguide and Ni ohmic contact(electrode) 1307 is formed underneath the n-type 4H-SiC (11-20) substrate 1301. The Al composition in the n-type 4H-AlGaN cladding layer 1302 maybe varied to relax the lattice mismatch between the AlGaN (n-type 4H-AlGaN cladding layer 1302 or p-type 4H-AlGaN cladding layer 1304) and the SiC substrate. The active layer 1303 has the quantum well and barrier layer. As shown in table 4(a), the composition of the well layer is undoped In0.1Ga0.9N, and the composition of the barrier layer is undoped In0.02Ga0.98N. The thickness of the well layer and the barrier layer is 4 nm. And the number of the well layer in the active layer 105 is three.

The laser structure on p-type 4H-SiC as shown in FIG. 13(b) has a p-type 4H-AlGaN initial layer as a part of the p-type 4H-AlGaN cladding layer 1304. Since the available p-GaN has carrier concentration up to 1×10¹⁸ cm⁻³ resulting the minimum attained ohmic contact resistance of 1×10⁻³ Ωcm², conventional GaN based laser diodes with the ridge waveguides 1305 in the p-type layer exhibits high series resistance owing to its narrow striped p-ohmic contacts. By using highly conductive p-SiC 1309 substrate with the resistivity of 0.01 Ωcm and large area backside contact, operation voltage is far reduced from that of conventional p-layer top laser diode.

All of the III-V nitride layers shown in FIG. 13(a) and (b) have 4H-polytype replicating that of the SiC substrate. The detailed structural parameters of the semiconductor lasers are summarized in Table 4. Table 4 discloses the thickness and carrier concentration each layers in one example. In Table 4 (a) an n-type AlGaN cladding layer has substantially same carrier concentration “1×10¹⁸ cm⁻³” as an n-type AlGaN initial layer, and an p-type GaN cladding layer has higher carrier concentration “5×10¹⁷ cm⁻³” than an n-type GaN cladding layer. And an undoped quantum wells have few or no carrie. In Table4 (b) a p-type AlGaN cladding layer has substantially same carrier concentration “1×10¹⁸ cm⁻³” as a p-type AlGaN initial layer, and an n-type GaN cladding layer has higher carrier concentration “5×10¹⁷ cm⁻³” than a p-type GaN cladding layer. And an undoped quantum wells have few or no carrie.

The detailed processing procedures are described for the embodiment on p-type SiC substrate 1309.

First, 380 nm-thick p-type 4H-Al_{0.5}Ga_{0.5}N initial layer is grown on p-type 4H-SiC(11-20) face substrate 1301 by molecular beam epitaxy(MBE) using the same epitaxial procedure explained in the first embodiment.

In a degreasing step the p-type 4H-SiC (11-20) substrate 1309 is first degreased using organic solvents.

In a wet chemical treatment step the p-type 4H-SiC (11-20) substrate 1309 is dipped in solutions in turn. First solution is HCl, second solution is HCl+HNO3 (3:1) and third solution HF.

In a thermal cleaning step the p-type 4H-SiC (11-20) substrate 1309 is thermally cleaned at 1000° C. for 30 min to make a flat and/or clean surface of the substrate, and then loaded into the MBE chamber.

The dopant Mg is introduced from the heated effusion cell in the MBE. Dopant atom is showing shallower acceptor level with low resistivity.

After the MBE growth, p-type 4H Al_{0.07}Ga_{0.93}N cladding layer 1304 having 0.5 μm-thickness, undoped InGaN multi-quantum well active layers 1303, n-type 4H Al_{0.07}Ga_{0.93}N cladding layer 1302 having 0.5 μm-thickness are grown by MOCVD. As explained in the first embodiment, n-type 4H AlGaN cladding layer 1302 and p-type 4H AlGaN cladding layer 1304, p-type 4H AlGaN with higher Al content maybe placed between the p-type 4H Al_{0.07}Ga_{0.93}N cladding layer 1304 and the active layer 1303. All of the regrowth layers exhibit 4H-polytype inheriting the atomic sequence of the MBE grown p-type 4H-AlGaN layer 1304.

Following dry etching processes selectively etches the n-type 4H-AlGaN cladding layer 1302 to form the straight ridge-shaped waveguide 1305.

After the etching steps, a SiO₂ film 1308 having 300 nm-thickness is deposited to confine the emitted light in the waveguide 1305. Then Ti/Au layer (electrode) 1310 as an n-ohmic contact 1310 is formed on the waveguide 1305. Wafer thinning process and Al—Si ohmic contact (electrode) 1311 formation for p-type SiC substrate followed by the cleaving are conducted to fabricate a blue-violet laser diodes on the non-polar face with vertical device configuration. In case the laser is formed on n-type SiC substrate, the top p-type ohmic contact is Ni/Au 1306, and back side contact for n-SiC is Ni 1307.

### Fourth Embodiment

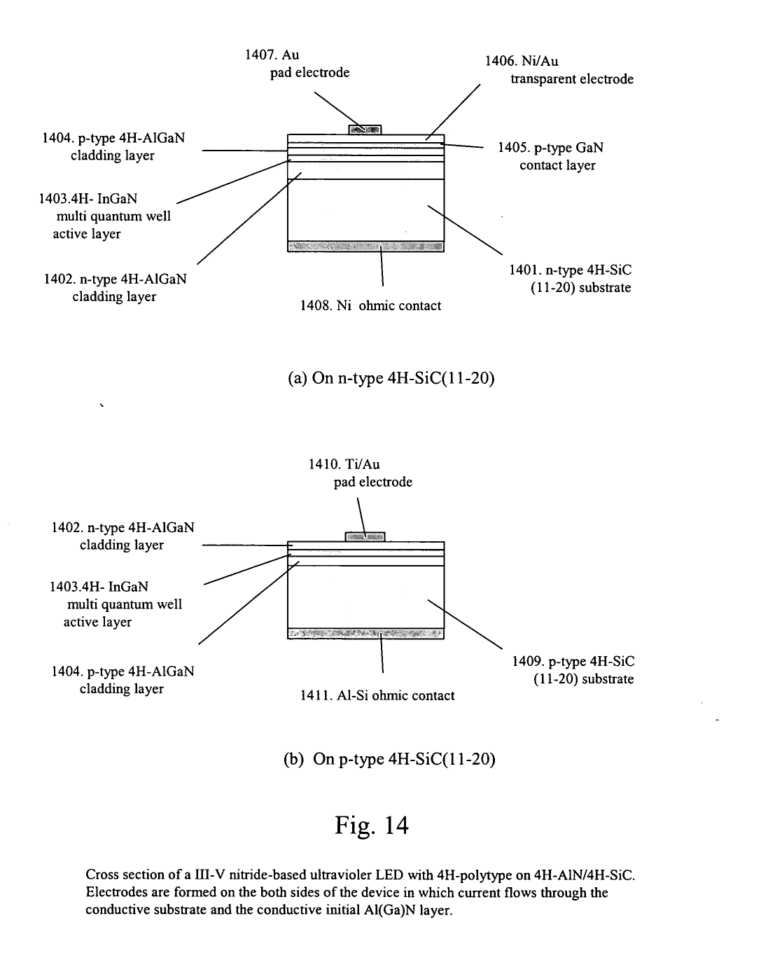

Referring next to FIG. 14(a) and (b), non-polar GaN-based ultraviolet light emitting diode (LED) on 4H-SiC (11-20) a-face substrates with two electrodes on the both sides of the LED chip are shown. The initial layer is conductive AlGaN layer and the 4H-SiC substrate is also conductive to enable the vertical device configuration. The emission efficiency from the quantum well in the LED on the non polar face is increased from that on the polar c-face with built-in electric field due to the polarization, which leads to high luminous efficiency together with low series resistance and operating voltage owing to its vertical device configuration.

As shown in FIG. 14(a) and (b), the epitaxial structure of the ultraviolet LED typically consists of p-type 4H Al_{0.25}Ga_{0.75}N cladding layer 1404, undoped 4H InAlGaN multi quantum well active layer 1403, n-type 4H Al_{0.25}Ga_{0.75}N cladding layer 1402.

The LED structure on n-type 4H-SiC 1401 as shown in FIG. 13(a) has an n-type 4H AlGaN initial layer as a part of the n-type 4H AlGaN cladding layer 1402. The Al composition in the n-type 4H-AlGaN cladding layer 1402 maybe varied to relax the lattice mismatch between the n-type 4H-AlGaN 1402 and the n-type 4H SiC (11-20) substrate 1401.

The LED structure on p-type 4H-SiC 1409 as shown in FIG. 13(b) has a p-type 4H-AlGaN initial layer as a part of the p-type 4H-AlGaN cladding layer 1404. As explained in the third embodiment, available p-type GaN or p-type AlGaN has carrier concentration up to 1×10¹⁸ cm⁻³ resulting the minimum attained ohmic contact resistance of 1×10⁻³ Ωcm². In order to obtain enough current spreading in the p-type layer top LED configuration, conventional GaN based LED with the p-type top layer uses transparent electrode such as thin Ni/Au 1406 with a Au top electrode 1407 together with Ni ohmic contact 1408 for n-type 4H-SiC (11-20) substrate as shown in FIG. 14(a). The transparent electrode may absorb the emitted light so that the thickness needs to be precisely controlled to avoid the optical loss in the electrode. Thus in view of reproducible manufacturing, n-type layer top vertical device configuration is desired.

As shown in FIG. 14(b), the use of highly conductive p-SiC substrate with the resistivity of 0.01 Ωcm and elimination of the transparent electrode enable reduction of the operating voltage as well as high luminous efficiency. All of the III-V nitride layers shown in FIG. 14(a) and (b) have 4H-polytype replicating that of the 4H-SiC substrate. The detailed structural parameters of the LED are summarized in Table 5. In Table 5 discloses the thickness and carrier concentration each layers in one example.

Table 5(a) shows a device having an n-type 4H-SiC (11-20) substrate. In Table 5(a) an n-type AlGaN cladding layer has substantially same carrier concentration “5×10¹⁷ cm⁻³” as a p-type AlGaN cladding layer, and an n-type AlGaN initial layer has substantially same carrier concentration “1×10¹⁸ cm⁻³” as an n-type GaN contact layer and n-type AlGaN initial layer. And an undoped quantum wells are not doped. The active layer 1403 has the quantum well and barrier layer. As shown in table 5(a), the composition of the well layer is undoped In0.02A10.15Ga0.848N, and the composition of the barrier layer is undoped A10.15Ga0.85N. The thickness of the well layer is 2 nm and the thickness of the barrier layer is 5 nm. And the number of the well layer in the active layer 1403 is three.

Table 5(b) shows a device having a p-type 4H-SiC (11-20)1409. In Table 5(b) an n-type AlGaN cladding layer 1402 has substantially same carrier concentration “5×10¹⁷ cm⁻³” as a p-type AlGaN cladding layer 1404, and an p-type GaN initial layer has lower carrier concentration “1×10¹⁸ cm⁻³” than an p-type AlGaN cladding layer. And an undoped quantum wells 1403 are not doped.

The detailed processing procedures are described for the embodiment on p-type SiC (11-20) substrate 1409.

First, 380 nm-thick p-type 4H-Al_{0.5}Ga_{0.5}N is grown on p-type 4H-SiC (11-20) face by molecular beam epitaxy (MBE) as is explained in the third embodiment.

In a degreasing step the p-type 4H-SiC (11-20) substrate 1409 is first degreased using organic solvents.

In a wet chemical treatment step the p-type 4H-SiC (11-20) substrate 1409 is dipped in solutions in turn. First solution is HCl, second solution is HCl+HNO3 (3:1) and third solution HF.

In a thermal cleaning step the p-type 4H-SiC (11-20) substrate 1309 is thermally cleaned at 1000° C. for 30 min to make a flat and/or clean surface of the substrate, and then loaded into the MBE chamber.

The dopant Mg is introduced from the heated effusion cell in the MBE. Dopant atom is showing shallower acceptor level with low resistivity.

After the MBE growth, p-Al_{0.25}Ga_{0.75}N cladding layer 1404 having 100 nm-thickness, undoped InAlGaN multi-quantum well active layers 1403, n-type Al_{0.25}Ga_{0.75}N cladding layer 1402 having 100 nm-thickness are grown by MOCVD. A p-type 4H-AlGaN with higher Al content than the cladding layer 1404 maybe placed between the p-cladding layer 1404 and the active layer to suppress the overflow of the electrons.

The multi quantum well 1403 may be InAlGaN(well layer)/AlGaN(barrier layer) quantum well to emit the ultraviolet light at around 340 nm. All of the regrowth layers exhibit 4H-polytype inheriting the atomic sequence of the MBE grown 4H-AlGaN layer.

Then Ti/Au layer 1410 as a pad electrode is formed on the n-type 4H-AlGaN cladding layer 1402. Wafer thinning and Al-Si ohmic contact 1411 formation for p-type SiC substrate are conducted to fabricate an ultra violet LED on the non-polar face with vertical device configuration.

### Fifth Embodiment

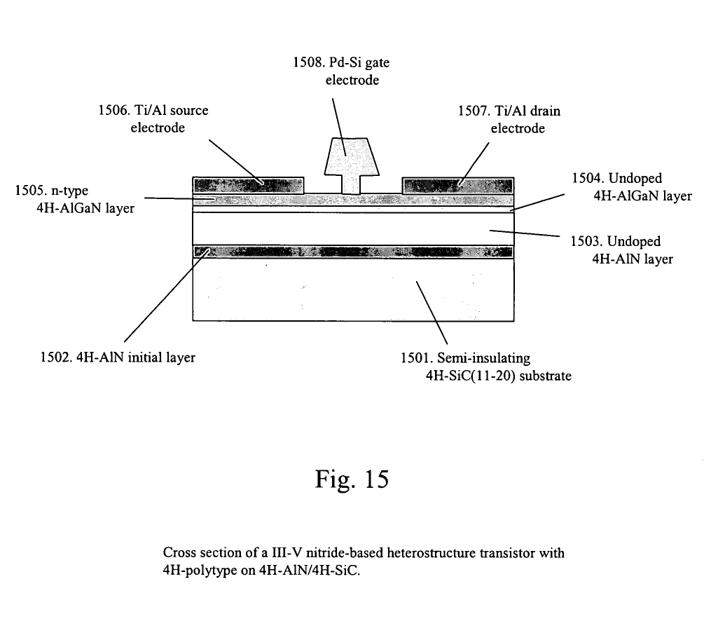

Referring next to FIG. 15, a non-polar III-V nitride-based transistor on non polar 4H-SiC (11-20) a-face is shown, in which electron mobility is enhanced in the AlGaN/GaN modulation-doped hetero structure. The epitaxial structure typically consists of n-type Al_{0.25}Ga_{0.75}N layer 1505 formed on undoped 4H-AlN layer 1503. Undoped 4H-Al_{0.25}Ga_{0.75}N layer 1504 may be inserted between the n-type 4H-Al_{0.25}Ga_{0.75}N layer 1505 and the undoped 4H-AlN layer 1503. The hetero structure is grown on a 4H-AlN initial layer 1502 as a buffer layer. All of the epitaxial layers have 4H-polytype and the layers are grown inheriting the polytype of the 4H-SiC substrate 1501. The epitaxial layer does not contain any build-in electric field due to the polarization. Comparing conventional polar AlGaN/GaN hetero structure transistors, the non-polar device makes the device design easier in which the potential barrier caused by the built-in electric field does not have to be taken into account. The device is not affected by the internal electric field which might increase the series resistance of the device. In addition, non polar AlGaN/InGaN/GaN pseudomorphic modulation doped structure would result in enhanced electron mobility with high enough sheet carrier concentration.

The detailed structure and the process sequences are described as follows. First, 4H-AlN initial layer 1502 as a buffer layer is grown on a semi-insulating 4H-SiC (11-20) substrate 1501 having 380 nm-thickness by molecular beam epitaxy (MBE) as is explained in the first embodiment.

In a degreasing step the p-type 4H-SiC (11-20) substrate 1501 is first degreased using organic solvents.

In a wet chemical treatment step the p-type 4H-SiC (11-20) substrate 1501 is dipped in solutions in turn. First solution is HCl, second solution is HCl+HNO3 (3:1) and third solution HF.

In a thermal cleaning step the p-type 4H-SiC (11-20) substrate 1501 is thermally cleaned at 1000° C. for 30 min to make a flat and/or clean surface of the substrate, and then loaded into the MBE chamber.

After the MBE growth, undoped 4H-AlGaN layer 1504 having 5 μm-thickness and n-type 4H-Al_{0.25}Ga_{0.75}N layer 1505 having 30 nm-thickness with carrier concentration of 2×10¹⁸ cm⁻³ are grown by MOCVD.

A dry etching process selectively etches the area to be isolated around the channel.

Then, Ti/Al n-type ohmic contact as a source electrode 1506 and p-type ohmic contact as a drain electrode 1507, and Pd—Si gate electrode 1508 is formed as a source, a drain and a gate of the field effect transistor (FET) as shown in FIG. 15. The fabricated FET is easy to be designed without any built-in electric field, which might lead to the enhanced electron mobility with lower series resistance.

The detailed structural parameters of the field effect transistor are summarized in Table 6. Table 6 discloses the thickness and carrier concentration each layers in one example. The uniformly doped n-type 4H-Al_{0.25}Ga_{0.75}N layer 1505 may be a d-doped layer with higher carrier concentration with atomic level thickness.

Although the above five embodiments are disclosed for III-V nitrides on 4H-SiC substrate, the substrate is not limited to SiC and may be, for example, ZnO. The substrate with 4H-polytype such as 4H-SiC and 4H-ZnO is useful for each embodiment. In addition, the III-V nitride layers may be chosen from any composition of B_{1-x-y-x}InₓAl_{y}Ga_{z}N (0≦x≦1, 0≦y≦1, 0≦z≦1) alloy. The used (11-20) substrate may be inclined less than 10 degree from the main face towards either <0001> or <1-100> direction.

Having fully described a preferred embodiment of the invention and various alternatives, those skilled in the art will recognize, given the teachings herein, that numerous alternatives and equivalents exist which do not depart from the invention. It is therefore intended that the invention not be limited by the foregoing description, but only by the appended claims.

TABLE 1

| | | | | Carrier |
|---|---|---|---|---|
| | | | | con- |
| | | | | centration |
| Layer | | Thickness | | (cm⁻³) |
| p-Al_{0.07}Ga_{0.93}N cladding layer | 106 | 0.5 | μm | 5 × 10¹⁷ |
| undoped | 105 | well 4 nm/barrier 4 nm | | |
| In_{0.1}Ga_{0.9}N/In_{0.02}Ga_{0.98}N | | | | |
| triple quantum wells | | | | |
| n-Al_{0.07}Ga_{0.93}N cladding layer | 104 | 1 | μm | 5 × 10¹⁷ |
| n-GaN base layer | 103 | 4 | μm | 1 × 10¹⁸ |
| undoped AlN initial layer | 102 | 380 | nm | |
| SiC substrate | 101 | | | |

TABLE 2

| | SiC | overgrown | poly-type | crystal | device |
|---|---|---|---|---|---|
| | substrate | AlN layer | matching | quality | performance |
| This | 4H-a-face | 4H-a-face | Yes | Excellent | Good |
| invention | | | | | |
| compared | 6H-a-face | 2H-a-face | No | Poor | Bad |
| example | | | | | |

TABLE 3

| | | | | Carrier |
|---|---|---|---|---|
| | | | | con- |
| | | | | centration |
| Layer | | Thickness | | (cm⁻³) |
| p-Al_{0.07}Ga_{0.93}N cladding layer | 1207 | 0.5 | μm | 5 × 10¹⁷ |
| undoped | 1206 | well 4 nm/barrier 4 nm | | |
| In_{0.1}Ga_{0.9}N/In_{0.02}Ga_{0.98}N | | | | |
| triple quantum wells | | | | |
| n-Al_{0.07}Ga_{0.93}N cladding layer | 1205 | 1 | μm | 5 × 10¹⁷ |
| n-GaN base layer | 1204 | 4 | μm | 1 × 10¹⁸ |
| n-GaN seed layer | 1203 | 1 | μm | 1 × 10¹⁸ |
| undoped AlN initial layer | 1202 | 380 | nm | |
| SiC substrate | 1201 | | | |

TABLE 4

| | | |
|---|---|---|
| | | Carrier |
| | | con- |
| | | centration |
| Layer | Thickness | (cm⁻³) |

(a) on n-type 4H—SiC(11-20)

| p-Al_{0.07}Ga_{0.93}N cladding layer | 1304 | 0.5 | μm | 5 × 10¹⁷ |
|---|---|---|---|---|
| undoped | 1303 | well 4 nm/barrier 4 nm | | |
| In_{0.1}Ga_{0.9}N/In_{0.02}Ga_{0.98}N | | | | |
| triple quantum wells | | | | |
| n-Al_{0.07}Ga_{0.93}N cladding layer | 1302 | 1 | μm | 1 × 10¹⁸ |
| n-Al_{0.5}Ga_{0.5}N initial layer | | 380 | nm | 1 × 10¹⁸ |
| SiC substrate | 1301 | | | |

(b) on p-type 4H—SiC(11-20)

| n-Al_{0.07}Ga_{0.93}N cladding layer | 1302 | 0.5 | μm | 5 × 10¹⁷ |
|---|---|---|---|---|
| undoped | 1303 | well 4 nm/barrier 4 nm | | |
| In_{0.1}Ga_{0.9}N/In_{0.02}Ga_{0.98}N | | | | |
| triple quantum wells | | | | |
| p-Al_{0.07}Ga_{0.93}N cladding layer | 1304 | 1 | μm | 1 × 10¹⁸ |
| p-Al_{0.5}Ga_{0.5}N initial layer | | 380 | nm | 1 × 10¹⁸ |
| SiC substrate | 1309 | | | |

TABLE 5

| | | |
|---|---|---|
| | | Carrier |
| | | concentration |
| Layer | Thickness | (cm⁻³) |

(a) on n-type 4H—SiC(11-20)

| p-GaN contact layer | 1405 | 5 | nm | 1 × 10¹⁸ |
|---|---|---|---|---|
| p-Al_{0.25}Ga_{0.75}N cladding layer | 1404 | 0.5 | μm | 5 × 10¹⁷ |
| undoped | 1403 | well 2 nm/ | | |
| In_{0.02Al0.15}Ga_{0.85}N/Al_{0.15}Ga_{0.85}N | | barrier 5 nm | | |
| triple quantum wells | | | | |
| n-Al_{0.25}Ga_{0.75}N cladding layer | 1402 | 1 | μm | 5 × 10¹⁷ |
| n-Al_{0.5}Ga_{0.5}N initial layer | | 380 | nm | 1 × 10¹⁸ |
| SiC substrate | 1401 | | | |

(b) on p-type 4H—SiC(11-20)

| | | | | |
|---|---|---|---|---|
| n-Al_{0.25}Ga_{0.75}N cladding layer | 1402 | 0.5 | μm | 5 × 10¹⁷ |

| | | |
|---|---|---|
| undoped | 1403 | well 2 nm/ |
| In_{0.02Al0.15}Ga_{0.85}N/Al_{0.15}Ga_{0.85}N | | barrier 5 nm |
| triple quantum wells | | |

| | | | | |
|---|---|---|---|---|
| p-Al_{0.25}Ga_{0.75}N cladding layer | 1404 | 1 | μm | 5 × 10¹⁷ |
| p-Al_{0.5}Ga_{0.5}N initial layer | | 380 | nm | 1 × 10¹⁸ |
| SiC substrate | 1409 | | | |

TABLE 6

| | | | | Carrier concentration |
|---|---|---|---|---|
| Layer | | Thickness | | (cm⁻³) |
| n-Al_{0.25}Ga_{0.73}N layer | 1505 | 15 | nm | 2 × 10¹⁸ |
| undoped Al_{0.25}Ga_{0.75}N layer | 1504 | 5 | nm | |
| undoped GaN layer | 1503 | 4 | μm | |
| undoped AlN initial layer | 1502 | 380 | nm | |
| SiC substrate | 1501 | | | |

1. A semiconductor device comprising a B_{1-x-y-z}InₓAl_{y}Ga_{z}N(0≦x≦1, 0≦y≦1, 0≦z≦1) alloy epitaxial film having 4H-polytype structure formed on a substrate having 4H-type structure.

2. The semiconductor device according to claim 1, wherein the substrate is silicon carbide.

3. The semiconductor device according to claim 1, wherein said B_{1-x-y-z}InₓAl_{y}Ga_{z}N (0≦x≦1, 0≦y≦1, 0≦z≦1) alloy epitaxial film is formed on a substrate having (11-20) face.

4. The semiconductor device according to claim 1, wherein said B_{1-x-y-z}InₓAl_{y}Ga_{z}N (0≦x≦1, 0≦y≦1, 0≦z≦1) alloy epitaxial film comprises AlN.

5. The semiconductor device according to claim 1, wherein a number of group III atoms are equal to a number of nitrogen atoms on a surface of said B_{1-x-y-z}InₓAl_{y}Ga_{z}N(0≦x≦1, 0≦y≦1, 0≦z≦1) alloy epitaxial film.

6. An optoelectronic device comprising,
a GaN-based epitaxial layers having 4H-polytype structure formed over a substrate having 4-H type and a waveguide formed on said GaN-based epitaxial layers having 4H-polytype, and
wherein said GaN-based epitaxial layers having 4H-polytype structure include an n-type layer, a p-type layer and an active layer, said active layer being formed between said n-type layer and said p-type layer.

7. The optoelectronic device according to claim 6, wherein a plurality of layers being formed between said waveguide and said substrate have 4H-type structure.

8. The optoelectronic device according to claim 6, wherein said substrate having 4-H type structure is SiC.

9. The optoelectonic device according to claim 6, wherein said GaN-based alloy epitaxial film is formed on a substrate having (11-20) face.

10. The optoelectonic device according to claim 6, wherein said GaN-based alloy epitaxial film comprises AlN.

11. The optoelectonic device according to claim 6, wherein a number of group III atoms are equal to a number of nitrogen atoms on a surface of said GaN-based alloy epitaxial film.

12. The optoelectronic device according to claim 6, wherein said waveguide is formed as a straight line perpendicular to either (0001) face or (1-100) face.

13. The optoelectronic device according to claim 6, further comprising AlN layer having 4H type structure between said GaN-based epitaxial layers having 4H-polytype structure and said substrate having 4-H type structure.

14. The optoelectronic device according to claim 13, further comprising an n-type region formed in said GaN-based epitaxial layers having 4H-polytype structure and in contact with said AlN layer having 4H type structure.

15. The optoelectronic device according to claim 13, further comprising no epitaxial region is contact with a side surface of said AlN layer having 4H type structure.

16. The optoelectronic device according to claim 6, further comprising conductive AlGaN layer having 4H type structure between said GaN-based epitaxial layers having 4H-polytype structure and said substrate having 4-H type structure.

17. The optoelectronic device according to claim 6, where said substrate having 4-H type structure exhibits p-type conduction.

18. The optoelectronic device according to claim 6, further comprising a first contact is formed on said waveguide and a second contact is formed under said substrate having 4-H type structure.

19. The optoelectronic device according to claim 18, wherein the first contact and the second contact includes Ni.

20. The optoelectronic device according to claim 18, wherein the first contact includes Ti and the second contact includes Al.

21. A semiconductor device comprising,
GaN-based epitaxial layers having 4H-polytype structure formed over a substrate having 4-H type structure and an electrode formed over said GaN-based epitaxial layers having 4H-polytype structure, and
wherein said GaN-based epitaxial layers having 4H-polytype structure include an n-type layer, a p-type layer.

22. The semiconductor device according to claim 21, wherein a plurality of layers being formed between said electrode and said substrate have 4H-type structure.

23. The semiconductor device according to claim 21, wherein said substrate having 4-H type structure is SiC.

24. The semiconductor device according to claim 21, wherein said GaN-based alloy epitaxial film is formed on a substrate having (11-20) face.

25. The optoelectonic device according to claim 21, wherein said GaN-based alloy epitaxial film comprises AlN.

26. The optoelectonic device according to claim 21, wherein a number of group III atoms are equal to a number of nitrogen atoms on a surface of said GaN-based alloy epitaxial film.

27. The optoelectronic device according to claim 21, further comprising AlN layer having 4H type structure between said GaN-based epitaxial layers having 4H-polytype structure and said substrate having 4-H type structure.

28. The optoelectronic device according to claim 21, further comprising conductive AlGaN layer having 4H type structure between said GaN-based epitaxial layers having 4H-polytype structure and said substrate having 4-H type structure.

29. The semiconductor device according to claim 21, where said substrate having 4-H type structure exhibits p-type or n-type conduction.

30. A semiconductor device comprising,
GaN-based epitaxial layers having 4H-polytype structure formed over a substrate having 4-H type structure, and a gate electrode, a source electrode and a drain electrode formed on said GaN-based epitaxial layers having 4H-polytype structure, and wherein said GaN-based epitaxial layers having 4H-polytype structure include an conductive layer, an undoped layer.

31. The semiconductor device according to claim 30, wherein a plurality of layers being formed between said gate electrode and said substrate have 4H-type structure.

32. The semiconductor device according to claim 30, wherein said substrate having 4-H type structure is SiC.

33. The semiconductor device according to claim 30, wherein said GaN-based alloy epitaxial film is formed on a substrate having (11-20) face.

34. The optoelectonic device according to claim 30, wherein said GaN-based alloy epitaxial film comprises AlN.

35. The optoelectonic device according to claim 30, wherein a number of group III atoms are equal to a number of nitrogen atoms on a surface of said GaN-based alloy epitaxial film.

36. The optoelectronic device according to claim 30, further comprising AlN layer having 4H type structure between said GaN-based epitaxial layers having 4H-polytype structure and said substrate having 4-H type structure.

37. The semiconductor device according to claim 30, wherein said AlN layer having 4H type structure includes an undoped layer and said undoped layer in contact with said GaN-based epitaxial layers having 4H-polytype structure.

38. The semiconductor device according to claim 30, wherein said n-type layer is contacted to said gate electrode, said source electrode and said drain electrode.

39. The semiconductor device according to claim 30, where said GaN-based epitaxial layers having 4H-polytype structure have a modulation-doped structure.

40. A method of forming a semiconductor device comprising,
forming GaN-based epitaxial layers having 4H-polytype structure on a substrate having 4H-type structure.

41. The method of a semiconductor device according to claim 40, wherein at least a part of said GaN-based epitaxial layers having 4H-polytype structure is grown by metal organic chemical vapor deposition or molecular beam epitaxy.

42. The method of a semiconductor device according to claim 40, wherein a first layer of said GaN-based epitaxial layers having 4H-polytype structure is grown by molecular beam epitaxy and a second layer of said GaN-based epitaxial layers having 4H-polytype structure is grown by metal organic chemical vapor deposition.

43. The method of a semiconductor device according to claim 40, wherein said GaN-based epitaxial layers having 4H-polytype structure are formed over 1000° C.

44. The method of a semiconductor device according to claim 40, wherein said GaN-based epitaxial layers comprises an AlN layer having 4H type structure as an initial layer and said AlN layer is grown by molecular beam epitaxy.

45. The method of a semiconductor device according to claim 40, wherein said substrate having 4-H type structure is treated in HCl acid, aqua regia and HF acid before said forming said GaN-based epitaxial layers having 4H-polytype structure.

46. The method of a semiconductor device according to claim 40, further comprising forming a waveguide on said GaN-based epitaxial layers having 4H-polytype structure.

47. The method of a semiconductor device according to claim 46, said waveguide and said GaN-based epitaxial layers having 4H-polytype structure are cleaved along to <0001> or <1-100> direction.

48. The method of a semiconductor device according to claim 40, further comprising etching a buffer layer selectively and forming a seed layer in contact with said buffer layer before forming said GaN-based epitaxial layers having 4H-polytype structure on said buffer layer, and
wherein said seed layer is formed in said GaN-based epitaxial layers having 4H-polytype structure.

49. The method of a semiconductor device according to claim 48, wherein a surface of said substrate having 4-H type structure is exposed after said etching.
